(19) United States
(12) Patent Application Publication
(10) Pub. No.: US 2010/0034719 A1
(43) Pub. Date: Feb. 11, 2010

(54) NOVEL LANTHANIDE BETA-DIKETONATE PRECURSORS FOR LANTHANIDE THIN FILM DEPOSITION

(76) Inventors: Christian DUSSARRAT, Wilmington, DE (US); Vincent M. Omarjee, Bear, DE (US)

Correspondence Address: AIR LIQUIDE;Intellectual Property, 2700 POST OAK BOULEVARD, SUITE 1800, HOUSTON, TX, 77056, US

(21) Appl. No.: 12/536,804

(22) Filed: Aug. 6, 2009

Related U.S. Application Data
(60) Provisional application No. 61/086,579, filed on Aug. 6, 2008.

(51) Int. Cl. B05D 5/12; C07F 5/00; H01L 21/314; C01F 17/00

(52) U.S. Cl. 423/263; 427/126.3; 534/15; 106/287.18

(57) ABSTRACT

Methods and compositions for depositing a film on one or more substrates include providing a reactor and at least one substrate disposed in the reactor. At least one lanthanide precursor is provided in vapor form and a lanthanide thin film layer is deposited onto the substrate.

### CROSS-REFERENCE TO RELATED APPLICATIONS

The present application claims the benefit of U.S. Provisional Application Ser. No. 61/086,579, filed Aug. 6, 2008, herein incorporated by reference in its entirety for all purposes.

### BACKGROUND

1. Field of the Invention

This invention relates generally to compositions, methods and apparatus used for use in the manufacture of semiconductor, photovoltaic, LCF-TFT, or flat panel type devices. More specifically, the invention relates to lanthanide precursors and methods for the deposition of lanthanide-containing thin films on a substrate.

2. Background of the Invention

A serious challenge currently faced by the semiconductor manufacturing industry is the development of new gate dielectric materials for DRAM and capacitors. For decades, silicon dioxide (SiO₂) has been used as a reliable dielectric, but as transistors have continued to shrink and the technology moved from “Full Si” transistor to “Metal Gate/High-k” transistors, the reliability of the SiO₂-based gate dielectric is reaching its physical limits. The need for new high dielectric constant materials and processes is increasing and it becomes more and more critical as the size for current technology is shrinking. It is hoped that a new generation of oxides, in particular those based on Lanthanides containing materials, may give significant advantages in capacitance compared to conventional dielectric materials.

However, there are inherent challenges in the deposition of lanthanide containing layers, and new materials and processes are required to address these. For instance, atomic layer deposition (“ALD”), which has been identified as an important thin film growth technique for semiconductor manufacturing, relies on sequential and saturating surface reactions of alternatively applied precursors, which are separated by inert gas purging. The surface-controlled nature of ALD enables the growth of thin films of high conformality and uniformity with an accurate thickness control.

The need for using new ALD processes to deposit rare earth materials is clear; unfortunately the successful integration or identification of compounds used for depositions into vapor deposition processes has proven to be difficult. Two classes of molecules are typically proposed: beta-diketonates and cyclopentadienyls. The former family of compounds is stable, but the melting points normally exceed 90° C., which makes them impractical with delivery efficiency very difficult to control (e.g. La(tmhd)₃'s melting point is as high as 260° C., and the related La(tmod)₃'s melting point is still 197° C.) and the latter family of compounds are ineffective as they exhibit low volatility and high melting point. Specific molecular design/formulation could help by both improving volatility and reducing the melting point. However, in process conditions, these classes of materials have proved limited in use. For instance, La(iPrCp)3 does not allow an ALD regime above 225° C.

As well as for ALD, new CVD processes are also required for rare earth metal materials. Other sources and methods of incorporating rare earth metal materials are being sought for new generations of integrated circuit devices.

Consequently, there exists a need for materials and methods which allow for the deposition of rare earth materials in semiconductor manufacturing processes. In particular, lanthanide containing precursors with low melting points and high volatility.

### BRIEF SUMMARY

The invention provides novel methods and compositions for the deposition of a lanthanide containing layer on a substrate. In an embodiment, a method for depositing a lanthanide containing layer on a substrate comprises providing a reactor, and at least one substrate disposed in the reactor. A precursor-containing vapor is introduced into the reactor. The vapor contains at least one precursor of the general formula (I):

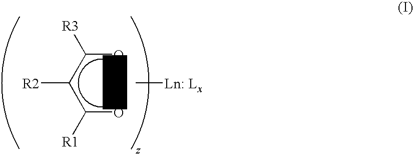

wherein Ln is independently selected from among the lanthanide group of elements; each L is independently a neutral ligand; z represents the number of beta-diketonate groups in the precursor, and inclusively ranges between 0 and 4; x represents the number of neutral ligands in the precursor, and inclusively ranges between 0 and 4; each R is independently selected from hydrogen and a C1-C5 aliphatic group, or aliphatic moiety. The reactor is maintained at a temperature of at least about 100° C. and the precursor-containing vapor is contacted with at least part of the substrate to form a lanthanide containing layer on the substrate through a vapor deposition process.

In another embodiment, a composition is provided, where the composition comprises a precursor of the general formula (I):

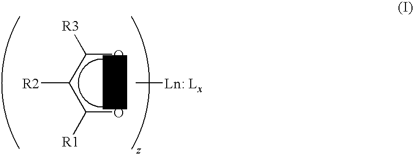

wherein Ln is independently selected from among the lanthanide group of elements; each L is independently a neutral ligand; z represents the number of beta-diketonate groups in the precursor, and inclusively ranges between 0 and 4; x represents the number of neutral ligands in the precursor, and inclusively ranges between 0 and 4; each R is independently selected from hydrogen and a C1-C5 aliphatic group, or aliphatic moiety.

Other embodiments of the current invention may include, without limitation, one or more of the following features:
the neutral ligand is one of: tetrahydrofuran (THF); diglyme; triglyme; tetraglyme; dimethyl ether (DME); and combinations thereof, and preferably the neutral ligand is tetraglyme;
the beta-diketonate is 2,2,6,6-tetramethyl-3,5-octadionato-, (“tmod”) and z=3, such that the precursor comprises a precursor of the general formula:

Ln(tmod)₃Lₓ
wherein
   L is a neutral ligand comprising at least one member selected from the group consisting of: tetrahydrofuran (THF); diglyme; triglyme; tetraglyme; dimethyl ether (DME); and combinations thereof;
the precursor has a melting point of less than about 70° C., and is preferably a liquid at room temperature;
a substrate containing a lanthanide layer;
a second precursor-containing vapor is introduced into the reactor, and the second precursor-containing vapor comprises a precursor containing at least one of the following elements: Ti, Ta, Bi, Hf, Zr, Pb, Nb, Mg, Al, Sr, Y, Ba, Ca, a lanthanide, and combinations thereof;
at least one oxidizing gas introduced into the reactor, and the oxidizing gas comprises at least one of: O₂; O₃; H₂O; H₂O₂; and mixtures thereof;
the deposition process is a chemical vapor deposition (“CVD”) type deposition process, or an atomic layer deposition (“ALD”) type process, which comprises a plurality of deposition cycles; and
the precursor is one of: Y(tmod)₃,tetraglyme; Er(tmod)₃,tetraglyme; Tb(tmod)₃,tetraglyme; and La(tmod)₃,tetraglyme.

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the conception and the specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### Notation and Nomenclature

Certain terms are used throughout the following description and claims to refer to various components and constituents. This document does not intend to distinguish between components that differ in name but not function. Generally as used herein, elements from the periodic table of elements may be abbreviated with their standard abbreviation (e.g. Sc=scandium; Y=yttrium, etc).

As used herein, the abbreviation, “tmod” refers to 2,2,6,6-tetramethyl-3,5-octadionato-; the abbreviation “tmhd” refers to 2,2,6,6-tetramethyl-3,5-heptanedionato; the abbreviation “iPr”, refers to an isopropyl group; and the abbreviation “Cp” refers to a cyclopentadienyl group.

As used herein, the term “lanthanide” or “lanthanide group” refers to the elements from the periodic table of elements whose atomic numbers are contained in the set of: 21, 39 and 57-71 (inclusive).

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ(NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

### BRIEF DESCRIPTION OF THE DRAWINGS

For a further understanding of the nature and objects for the present invention, reference should be made to the following detailed description, taken in conjunction with the accompanying drawings, in which like elements are given the same or analogous reference numbers and wherein:

FIG. 1 illustrates graphical results of a thermogravimetric analysis of a one embodiment of the current invention;

FIG. 2 illustrates graphical results of a comparative thermogravimetric analysis;

FIG. 3 illustrates graphical results of a thermogravimetric analysis of a second embodiment of the current invention;

FIG. 4 illustrates graphical results of a thermogravimetric analysis of a third embodiment of the current invention;

FIG. 5 illustrates graphical results of a thermogravimetric analysis of a one embodiment of the current invention; and

FIG. 6 illustrates graphical results of a thermogravimetric analysis of a fifth embodiment of the current invention.

### DESCRIPTION OF PREFERRED EMBODIMENTS

The invention provides novel methods and compositions for the deposition of a lanthanide containing layer on a substrate. In an embodiment a method for depositing a lanthanide containing layer on a substrate comprises providing a reactor, and at least one substrate disposed in the reactor. A precursor-containing vapor is introduced into the reactor. The vapor contains at least one precursor of the general formula (I):

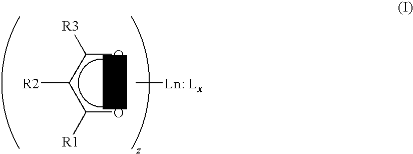

wherein Ln is independently selected from among the lanthanide group of elements; each L is independently a neutral ligand; z represents the number of beta-diketonate groups in the precursor, and inclusively ranges between 0 and 4; x represents the number of neutral ligands in the precursor, and inclusively ranges between 0 and 4; each R is independently selected from hydrogen and a C1-C5 aliphatic group, or aliphatic moiety. The reactor is maintained at a temperature of at least about 100° C., and the precursor-containing vapor is contacted with at least part of the substrate to form a lanthanide containing layer on the substrate through a vapor deposition process.

In some embodiments, the present invention provides lanthanide-containing compounds (i.e., lanthanide-containing complexes, precursors) that include at least one beta-diketonate ligand and methods of using the same. In some embodiments, the present invention provides metal-containing compounds having at least one asymmetric beta-diketonate ligand as a substituent selected to have greater degrees of freedom compared to other existing solutions of simple beta-diketonates known in the art.

In some embodiments, the present invention provides lanthanide-containing compounds (i.e., lanthanide-containing complexes, precursors) which include three beta-diketonate ligands, and at least one adduct. These compounds are designed so as to reduce the melting point of the compound such that the melting point is below 70° C., and preferably, so that the compound is a liquid at room temperature. The high thermal stability of these compounds is sought to be maintained. The combination of high thermal stability and low melting point makes such compounds suitable for use in vapor deposition methods.

Without seeking to be bound by theory, it is believed that the use of unsymmetrical beta-diketonates as anionic ligands bonded to the lanthanide, with at least one neutral ligand, increase the entropy of and therefore reduces dramatically the melting point of the compound, as compared to other lanthanide compounds.

Further, it has also been found that the stability of the compound is maintained when the C substituting the beta-diketonate skeleton is not bonded to any hydrogen. Since volatility should not be degraded, in some embodiments the preferred beta-diketonate is preferentially tmod (2,2,6,6-tetramethyl-3,5-octadionato-).

In order to increase the entropy of the resulting compound, while not degrading its volatility, triglyme or tetraglyme may be selected as the neutral ligand in some embodiments. Some common lanthanide precursors available present many constraint and drawbacks for an easy use in vapor deposition process. For instance, fluorinated precursors can generate LnF3 as a by product. This by-product is known to be difficult to remove. It becomes obvious that fluorinated-free compounds are preferred and needed. The presented novel precursors allow an excellent vapor pressure and a good thermal stability which means they have the same advantages as a fluorinated compounds without the drawbacks.

In some embodiments, the precursor may be one of the following: Y(tmod)₃,tetraglyme; Er(tmod)₃,tetraglyme; Tb(tmod)₃,tetraglyme; La(tmod)₃,tetraglyme; Sc(tmod)₃,tetraglyme; Ce(tmod)₃,tetraglyme; Pr(tmod)₃,tetraglyme, Nd(tmod)₃,tetraglyme; Pm(tmod)₃,tetraglyme; Sm(tmod)₃,tetraglyme; Eu(tmod)₃,tetraglyme; Gd(tmod)₃,tetraglyme; Dy(tmod)₃,tetraglyme; Ho(tmod)₃,tetraglyme; Tm(tmod)₃,tetraglyme; Yb(tmod)₃,tetraglyme; and Lu(tmod)₃,tetraglyme.

The disclosed precursors may be deposited to form a thin film layer using any deposition methods known to those of skill in the art. Examples of suitable deposition methods include without limitation, conventional CVD, low pressure chemical vapor deposition (LPCVD), plasma enhanced chemical vapor depositions (PECVD), atomic layer deposition (ALD), pulsed chemical vapor deposition (P-CVD), plasma enhanced atomic layer deposition (PE-ALD), or combinations thereof.

In an embodiment, the precursor is introduced into a reactor in vapor form. The precursor in vapor form may be produced by vaporizing a liquid precursor solution, through a conventional vaporization step such as direct vaporization, distillation, or by bubbling an inert gas (e.g. N₂, He, Ar, etc.) into the precursor solution and providing the inert gas plus precursor mixture as a precursor vapor solution to the reactor. Bubbling with an inert gas may also remove any dissolved oxygen present in the precursor solution.

The reactor may be any enclosure or chamber within a device in which deposition methods take place such as without limitation, a cold-wall type reactor, a hot-wall type reactor, a single-wafer reactor, a multi-wafer reactor, or other types of deposition systems under conditions suitable to cause the precursors to react and form the layers.

Generally, the reactor contains one or more substrates on to which the thin films will be deposited. The one or more substrates may be any suitable substrate used in semiconductor, photovoltaic, flat panel, or LCD-TFT device manufacturing. Examples of suitable substrates include without limitation, silicon substrates, silica substrates, silicon nitride substrates, silicon oxy nitride substrates, tungsten substrates, or combinations thereof. Additionally, substrates comprising tungsten or noble metals (e.g. platinum, palladium, rhodium, or gold) may be used. The substrate may also have one or more layers of differing materials already deposited upon it from a previous manufacturing step.

In some embodiments, in addition to the precursor, a reactant gas may also be introduced into the reactor. In some of these embodiments, the reactant gas may be an oxidizing gas such as one of oxygen, ozone, water, hydrogen peroxide, nitric oxide, nitrogen dioxide, radical species of these, as well as mixtures of any two or more of these. In some embodiments, and depending on what type of film is desired to be deposited, a second precursor may be introduced into the reactor. The second precursor may be introduced into the reactor in vapor form, as discussed above. The second precursor may comprise another metal source, such as copper, praseodymium, manganese, ruthenium, titanium, tantalum, bismuth, zirconium, hafnium, lead, niobium, magnesium, aluminum, strontium, yttrium, barium, calcium, a member of the lanthanide group, or mixtures of these. In embodiments where a second precursor is utilized, the resultant film deposited on the substrate may contain at least two different material/element types.

The first precursor and any optional reactants or precursors may be introduced sequentially (as in ALD) or simultaneously (as in CVD) into the reaction chamber. In some embodiments, the reaction chamber is purged with an inert gas between the introduction of the precursor and the introduction of the reactant. In one embodiment, the reactant and the precursor may be mixed together to form a reactant/precursor mixture, and then introduced to the reactor in mixture form. In some embodiments, the reactant may be treated by a plasma, in order to decompose the reactant into its radical form. In some of these embodiments, the plasma may generally be at a location removed from the reaction chamber, for instance, in a remotely located plasma system. In other embodiments, the plasma may be generated or present within the reactor itself. One of skill in the art would generally recognize methods and apparatus suitable for such plasma treatment.

Depending on the particular process parameters, deposition may take place for a varying length of time. Generally, deposition may be allowed to continue as long as desired or necessary to produce a film with the necessary properties. Typical film thicknesses may vary from several hundred angstroms to several hundreds of microns, depending on the specific deposition process. The deposition process may also be performed as many times as necessary to obtain the desired film. For instance, ALD type depositions may be make use of a plurality of deposition cycles.

In some embodiments, the temperature and the pressure within the reactor are held at conditions suitable for ALD or CVD depositions. For instance, the pressure in the reactor may be held between about 1 Pa and about 10⁵ Pa, or preferably between about 25 Pa and 10³ Pa, as required per the deposition parameters. Likewise, the temperature in the reactor may be held between about 100° C. and about 500° C., preferably between about 150° C. and about 350° C.

In some embodiments, the precursor vapor solution and the reaction gas, may be pulsed sequentially or simultaneously (e.g. pulsed CVD) into the reactor. Each pulse of precursor may last for a time period ranging from about 0.01 seconds to about 10 seconds, alternatively from about 0.3 seconds to about 3 seconds, alternatively from about 0.5 seconds to about 2 seconds. In another embodiment, the reaction gas may also be pulsed into the reactor. In such embodiments, the pulse of each gas may last for a time period ranging from about 0.01 seconds to about 10 seconds, alternatively from about 0.3 seconds to about 3 seconds, alternatively from about 0.5 seconds to about 2 seconds.

### EXAMPLES

The following non-limiting examples are provided to further illustrate embodiments of the invention. However, the examples are not intended to be all inclusive and are not intended to limit the scope of the inventions described herein.

### Example 1

### Comparison of La(tmod)₃,tetraglyme and La(tmod)₃

A thermogravimetric (“TG-DTA) analysis of compositions according to some embodiments of the current invention were performed. As comparison, an un-adducted sample of a lanthanide precursor was also subjected to analysis.

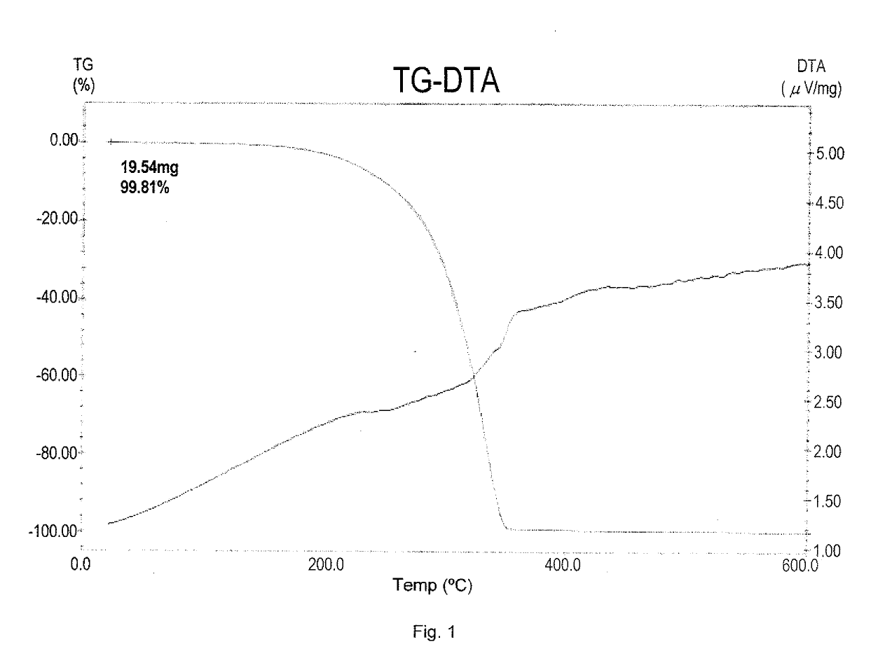

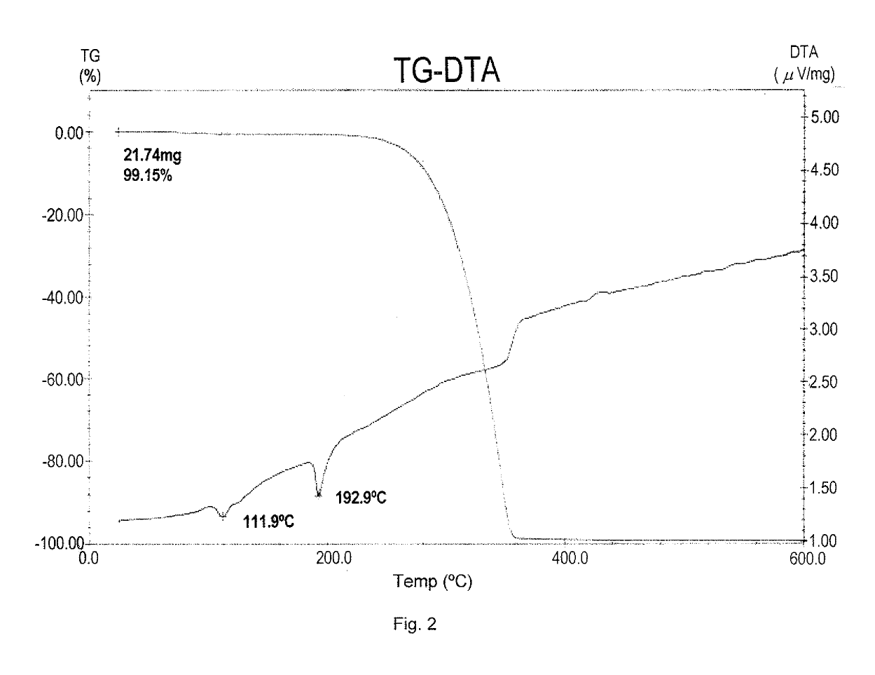

FIG. 1 shows the graphical results obtained for La(tmod)₃,tetraglyme, and by way of comparison, FIG. 2 shows the graphical results obtained for La(tmod)₃.

While the molecule is a liquid in case of La(tmod)₃,tetraglyme, the other compound melts at 192 C, a very high temperature, with no or limited meaning for vapor deposition applications. It was found that the La(tmod)₃,tetraglyme is much easier to handle and that its volatility and thermal stability are not affected or are slightly improved, as shown by the full evaporation temperature and the residue level respectively. From sublimation conditions, a higher volatility was clearly observed for the adducted compound, most likely because of its liquid nature. It should be also noted that as a liquid, the molecule is easier to purify, thereby resulting in easier and more cost-effective manufacturing.

For instance, the authors found that solid La(tmod)₃ is a very stable precursor. The TG-DTA in atmospheric condition reveals no decomposition at temperature as high as 375° C. Moreover, it was shown that La(tmod)₃,tetraglyme as expected is a liquid. The stability was conserved and no sign of decomposition appears at 375 C in TG-DTA conditions. The gain in volatility and the lower melting point was demonstrated. Similar results for other embodiments of the current invention are shown in subsequent examples.

### Example 2

### Comparison of Y(tmod)₃,tetraglyme and Y(tmod)₃

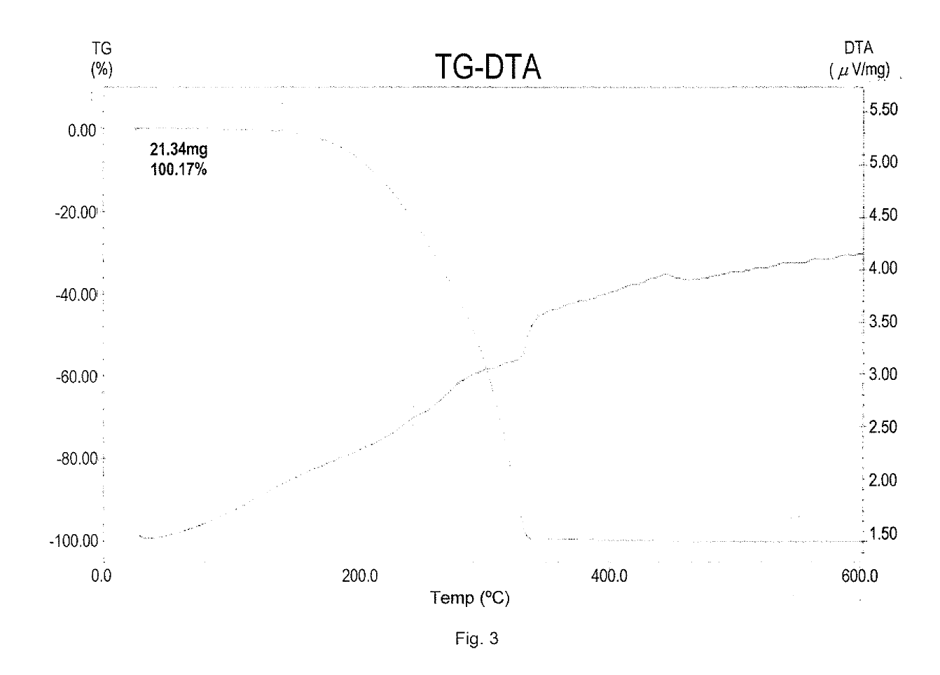

A similar analysis as described in Example 1 was performed for these compounds. The results were also in accordance with those described in Example 1 (e.g. the adducted molecule was a liquid and left no residue after full evaporation), and these results are shown graphically for Y(tmod)₃,tetraglyme as FIG. 3.

### Example 3

### Comparison of Er(tmod)₃,tetraglyme and Er(tmod)₃

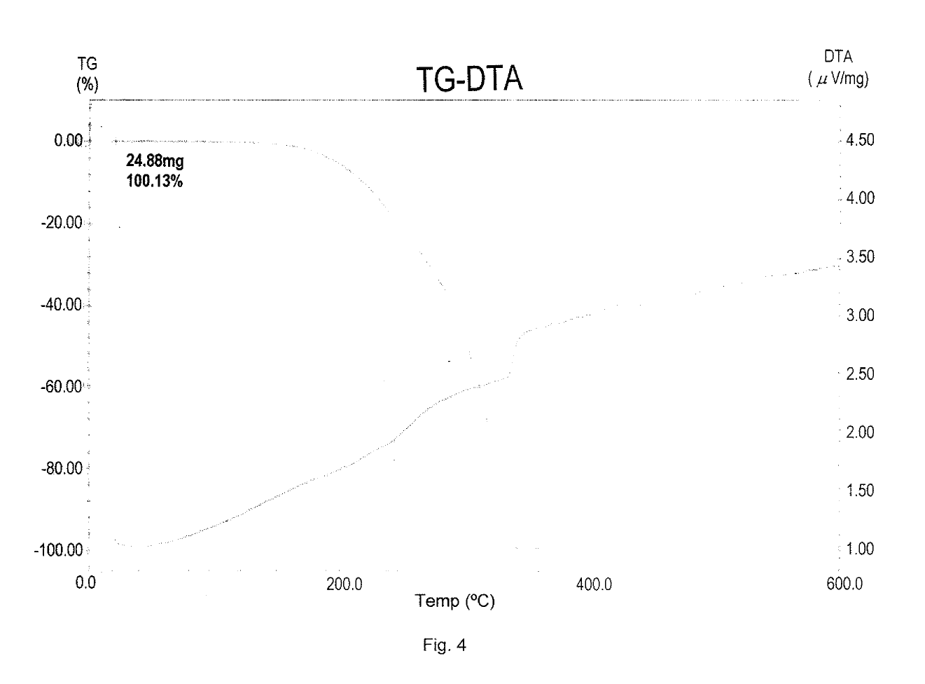

A similar analysis as described in Example 1 was performed for these compounds. The results were also in accordance with those described in Example 1 (e.g. the adducted molecule was a liquid and left no residue after full evaporation), and these results are shown graphically for Er(tmod)₃,tetraglyme as FIG. 4.

### Example 4

### Comparison of Yb(tmod)₃,tetraglyme and Yb(tmod)₃

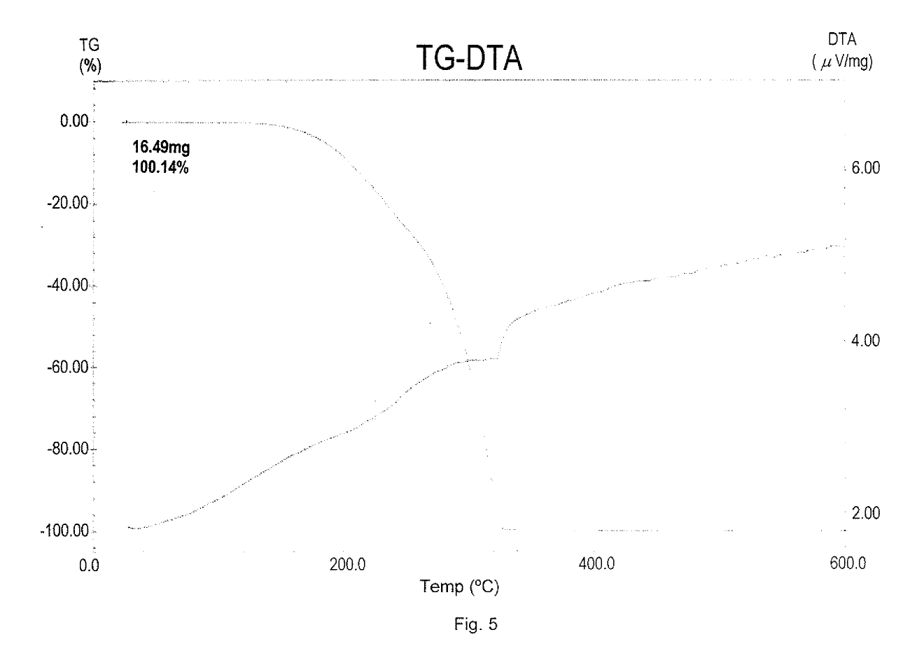

A similar analysis as described in Example 1 was performed for these compounds. The results were also in accordance with those described in Example 1 (e.g. the adducted molecule was a liquid and left no residue after full evaporation), and these results are shown graphically for Yb(tmod)₃,tetraglyme as FIG. 5.

### Example 5

### Comparison of Lu(tmod)₃,tetraglyme and Lu(tmod)₃

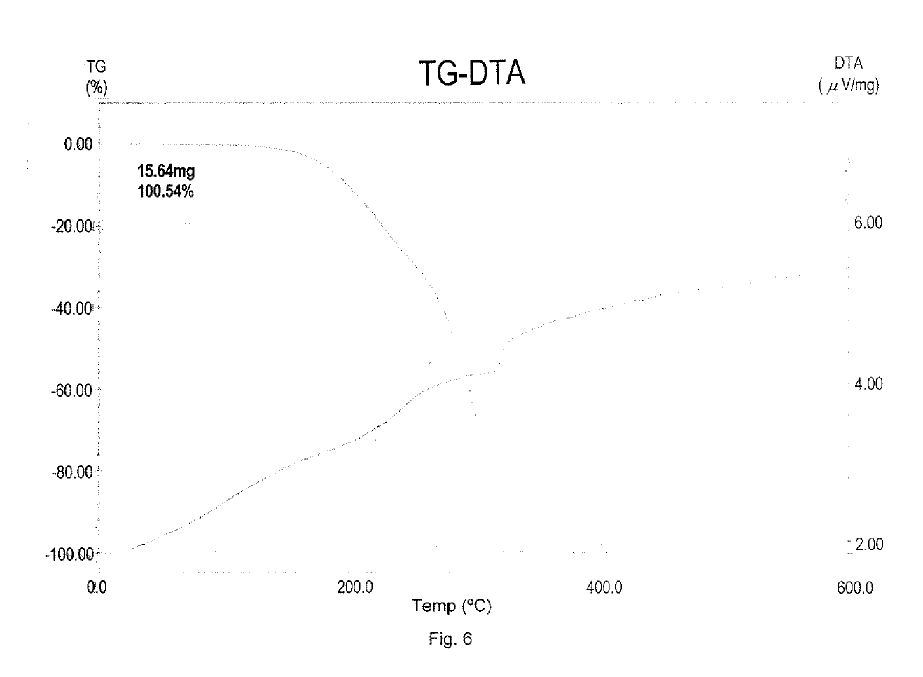

A similar analysis as described in Example 1 was performed for these compounds. The results were also in accordance with those described in Example 1 (e.g. the adducted molecule was a liquid and left no residue after full evaporation), and these results are shown graphically for Lu(tmod)₃,tetraglyme as FIG. 6.

While embodiments of this invention have been shown and described, modifications thereof can be made by one skilled in the art without departing from the spirit or teaching of this invention. The embodiments described herein are exemplary only and not limiting. Many variations and modifications of the composition and method are possible and within the scope of the invention. Accordingly the scope of protection is not limited to the embodiments described herein, but is only limited by the claims which follow, the scope of which shall include all equivalents of the subject matter of the claims.

What is claimed is:

1. A method of forming a lanthanide containing layer on a substrate, comprising:
a) providing a reactor and at least one substrate disposed therein;
b) introducing a precursor-containing vapor into the reactor, wherein the precursor-containing vapor comprises at least one precursor of the general formula (I): 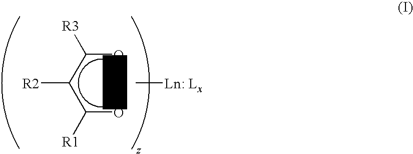
wherein:
Ln is at least one member selected from the lanthanide group of elements;
each L is independently a neutral ligand;
0≦z≦4, where z represents a number of beta-diketonate groups;
0≦x≦4, where x represents a number of neutral ligands;
each R is independently selected from the group consisting of: hydrogen and a C1-C5 aliphatic group, or aliphatic moiety;
c) maintaining the reactor at a temperature of at least about 100° C.; and
d) contacting the precursor-containing vapor with at least part of the substrate, and forming a lanthanide containing layer on the substrate through a vapor deposition process.

2. The method of claim 1, wherein the neutral ligand comprises at least one member selected from the group consisting of: tetrahydrofuran (THF); diglyme; triglyme; tetraglyme; dimethyl ether (DME); and combinations thereof.

3. The method of claim 1, wherein the neutral ligand is tetraglyme.

4. The method of claim 1, wherein the beta-diketonate is 2,2,6,6-tetramethyl-3,5-octadionato-, (“tmod”) and z=3, such that the precursor comprises a precursor of the general formula:
Ln(tmod)₃Lₓ
wherein:
L is a neutral ligand comprising at least one member selected from the group consisting of: tetrahydrofuran (THF); diglyme; triglyme; tetraglyme; dimethyl ether (DME); and combinations thereof.

5. The method of claim 1, wherein the precursor has a melting point of less than about 70° C.

6. The method of claim 5, wherein the precursor is a liquid at room temperature.

7. The method of claim 1, further comprising introducing a second precursor-containing vapor into the reactor, wherein the second precursor-containing vapor comprises a precursor containing at least one of the following elements: Ti, Ta, Bi, Hf, Zr, Pb, Nb, Mg, Al, Sr, Y, Ba, Ca, a lanthanide, and combinations thereof.

8. The method of claim 1, further comprising introducing at least one oxidizing gas into the reactor, wherein the oxidizing gas comprises at least one member selected from the group consisting of: O₂; O₃; H₂O; H₂O₂; and mixtures thereof.

9. The method of claim 1, wherein the vapor deposition process is a chemical vapor deposition (CVD) type process.

10. The method of claim 1, wherein the vapor deposition process is an atomic layer deposition (ALD) type process, comprising a plurality of deposition cycles.

11. The method of claim 1, wherein the precursor comprises at least one member selected from the group consisting of: Y(tmod)₃,tetraglyme; Er(tmod)₃,tetraglyme; Tb(tmod)₃,tetraglyme; and La(tmod)₃,tetraglyme.

12. A substrate containing a lanthanide layer comprising the product of the method of claim 1.

13. A composition comprising at least one precursor of the general formula (I): 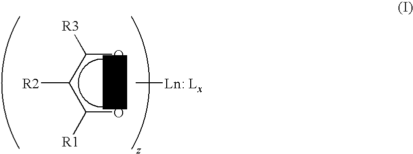
wherein:
Ln is at least one member selected from the lanthanide group of elements;
each L is independently a neutral ligand;
0≦z≦4, where z represents a number of beta-diketonate groups;
0≦x≦4, where x represents a number of neutral ligands; and
each R is independently selected from the group consisting of: hydrogen and a C1-C5 aliphatic group, or aliphatic moiety.

14. The composition of claim 13, wherein comprises at least one member selected from the group consisting of: tetrahydrofuran (THF); diglyme; triglyme; tetraglyme; dimethyl ether (DME); and combinations thereof.

15. The composition of claim 13, wherein the precursor has a melting point of less than about 70° C.

16. The composition of claim 15, wherein the precursor is a liquid at room temperature.

17. The composition of claim 13, wherein the precursor comprises at least one member selected from the group consisting of: Y(tmod)₃,tetraglyme; Er(tmod)₃,tetraglyme; Tb(tmod)₃,tetraglyme; and La(tmod)₃,tetraglyme.
